(19) United States
(12) Patent Application Publication
(10) Pub. No.: US 2013/0223152 A1
(43) Pub. Date: Aug. 29, 2013

(54) CLOCK GENERATOR

(71) Applicant: Elpida Memory, Inc., (US)

(72) Inventors: Marco PASSERINI, Lozza (VA) (IT); Stefano SIVERO, Capriate San Gervasio (BG) (IT)

(73) Assignee: ELPIDA MEMORY, INC., Tokyo (JP)

(21) Appl. No.: 13/827,244

(22) Filed: Mar. 14, 2013

Related U.S. Application Data
(63) Continuation-in-part of application No. 13/196,394, filed on Aug. 2, 2011.

(51) Int. Cl. H03K 3/011; G11C 16/32

(52) U.S. Cl. CPC H03K 3/011; G11C 16/32
USPC 365/185.18; 327/292

(57) ABSTRACT

A clock generator or oscillating circuit is provided to generate a clock signal with high Power Supply Rejection Ratio (PSSR), or a stable clock signal that is resistant to variations in the power supply. The clock generator or oscillating circuit may also adjust the clock period (T) of the clock signal, either or both upwards and downwards, around its central value to compensate fabrication process variations.

### CROSS REFERENCE TO RELATED APPLICATIONS

The present application is a continuation-in-part application of U.S. patent application Ser. No. 13/196,394, filed Aug. 2, 2011, which is published as U.S. Patent Application Publication No. 2013-0033947 A1, the disclosures of which are incorporated herein in their entirety by reference.

### FIELD OF THE DISCLOSURE

The present invention relates to a clock generator.

The present disclosure relates to a clock generator. The disclosure particularly, but not exclusively, relates to a clock generator generating clock signals, and the following description is made with reference to this field of application for convenience of explanation only.

The disclosure particularly, but not exclusively, relates to a clock generator that generates RC-type trimmable clock signals with high Power Supply Rejection Ratio (PSRR), and the following description is made with reference to this field of application for convenience of explanation only.

### BACKGROUND OF THE DISCLOSURE

In a general definition, clock signals are repetitive digital signals, e.g., voltage waves toggling from a low logic state “O” to a high logic state “1”. The duty-cycle for these signals, being defined as the ratio between the time the signal is at logic state “1” over the repetition period or clock period, can be any value between 0 and 1. In many practical applications, the duty-cycle is 0.5, or ½.

Clock signals are needed in electronic devices for a variety of different circuits, blocks, sub-systems or systems. Some examples include microprocessors or microcontrollers, DC-DC converters, switched capacitor filters and so on. In a limited number of cases, the clock period changes during time, for example with respect to different working phases of the corresponding device, while in the most common applications, the clock period is instead fixed and it does not vary over time.

Moreover, for instance during a testing phase of an electronic device, it is often required to configure the clock period or clock phase among a range of possible values. Sometimes, it might be needed to finely adjust the clock period or clock phase to match a designed target. For example, it is sometimes needed to operate an electronic device at a different speed or to correct a clock period value or clock phase to compensate some fabrication process spread.

Digital oscillators or clock generators are electric circuits used to generate digital clock signals. Different architectures of the oscillators or clock generators are described in U.S. patent application Ser. No. 13/196,394.

An oscillator with temperature compensation and a clock output inhibition control is disclosed for instance in the U.S. Pat. No. 6,052,035.

In other cases, it may be also desirable to have different clock signals with a precise time difference between them. As an example, two signals with a time difference between their rising edge, same period and same duty cycle could be useful to generate different phase signals needed for a memory reading phase. For example, it may be a reading phase of a ROM or a RAM memory.

For clock signals in memories, it is often desired that the clock signals have high Power Supply Rejection Ratio (PSSR). The PSSR is an important parameter for power stability. It provides information on the influence of input voltage variations on the stability of the output voltage. Higher PSSR means that the output voltage is more resistant to input voltage variations, and thereby enabling more stable performance of the electronic circuit. Clock signals with high PSSR are the signals that are resistant to power supply variations, thereby providing stable clock signals to the electronic circuit receiving such signals.

### SUMMARY

According to an embodiment, a device includes a clock generating circuit including a first comparator circuit and a second comparator circuit which work complementary to each other to generate a first signal and a second signal having an opposite phase to the first signal, a first reference circuit including a first capacitor and a first resistance to produce, in response to the second signal, a first reference voltage supplied to the first comparator circuit, and a second reference circuit including a second capacitor and a second resistance to produce, in response to the first signal, a second reference voltage supplied to the second comparator circuit.

According to another embodiment, a device includes a clock generating circuit includes a first comparator circuit and a second comparator circuit which work complementary to each other to generate a first signal and a second signal having an opposite phase to the first signal, a first reference circuit producing, in response to the second signal, a first reference voltage supplied to the first comparator circuit, and including a first transistor coupled between a first power supply line and a reference input node of the first comparator and including a gate supplied with the second signal, a second transistor coupled between the reference input node of the first comparator and a second power supply line and including a gate supplied with the second signal, a first capacitor coupled between the reference input node of the first comparator and the second power supply line, and a first resistance coupled between the reference input node of the first comparator and the second transistor.

According to still another embodiment, a device includes a clock generating circuit including a first comparator circuit and a second comparator circuit which work complementary to each other to generate a first signal and a second signal having an opposite phase to the first signal, a first reference circuit producing, in response to the second signal, a first reference voltage supplied to the first comparator circuit, the first reference voltage varying in a voltage level, and a second reference circuit producing, in response to the first signal, a second reference voltage supplied to the second comparator circuit, the second reference voltage varying in a voltage level.

### BRIEF DESCRIPTION OF THE DRAWINGS

The characteristics and advantages of the oscillator or clock generator according to the disclosure will be apparent from the following description of embodiments thereof given by way of indicative and non-limiting example with reference to the annexed drawings, in which:

FIG. 1 schematically illustrates a block diagram of an oscillator or clock generator according to an embodiment of the disclosure.

FIG. 2 schematically shows a time diagram of the output signals from the master and slave oscillators of FIG. 1.

FIG. 3A schematically shows an embodiment of a master oscillator of FIG. 1.

FIG. 3B schematically shows an embodiment of a slave oscillator of FIG. 1.

FIG. 4 schematically shows a time diagram of signals of the master and slave oscillators of FIGS. 3A and 3B.

FIG. 5A schematically shows a clock generator having more than one slave oscillators connected in parallel according to a second embodiment of the invention.

FIG. 5B schematically shows a clock generator having more than one slave oscillators connected in series according to a third embodiment of the invention.

FIG. 5C schematically shows a time diagram according to a fourth embodiment of the invention.

FIG. 6A schematically shows a memory architecture indicative of a fifth embodiment of the invention.

FIG. 6B schematically shows a time diagram relating to the memory architecture of FIG. 6A.

FIG. 7A schematically shows a configurable current mirror for the slave oscillator according to a sixth embodiment of the invention.

FIG. 7B schematically shows a configurable capacitance block for the slave oscillator according to a seventh embodiment of the invention.

FIG. 8A schematically shows a seventh embodiment of the clock generator according to the present disclosure;

FIG. 8B schematically shows a time diagram of the waveforms associated with the embodiment shown in FIG. 8A;

FIG. 8C schematically shows an exemplary clock signal in a square waveform;

FIG. 9A schematically shows an eighth embodiment of the clock generator according to the present disclosure with trimming options;

FIG. 9B schematically shows a ninth embodiment of the clock generator according to the present disclosure with trimming options;

FIG. 9C schematically shows a tenth embodiment of the clock generator according to the present disclosure with the trimming options;

### DETAILED DESCRIPTION OF THE EMBODIMENTS

One of representative examples of a technological concept of the present disclosure which seeks to solve, at least, the below mentioned problems while achieving the above mentioned advantages will be described. The claimed contents of the present application are not limited to the technological concept below described but described in the claims of the present application.

While the preferred embodiments according to the invention will described in detail below, the terms “master” and “slave” are used throughout the specification and claims merely to distinguish two clock signals and generators, each clock signal having a different phase from the other and a slave clock generator being provided with the output signal of a master clock generator to generate an output clock signal. These terms should not be interpreted in a way to limit the function of each clock generator or each clock generator's output signal. For example, the master clock signal is not necessarily provided to a so-called master circuit element, and the slave clock signal is not necessarily provided to a so-called slave circuit element which has a master-slave relationship with the master circuit element. Since the term “oscillator” and “clock generator” have an equivalent meaning, those will be used interchangeably throughout the whole specification.

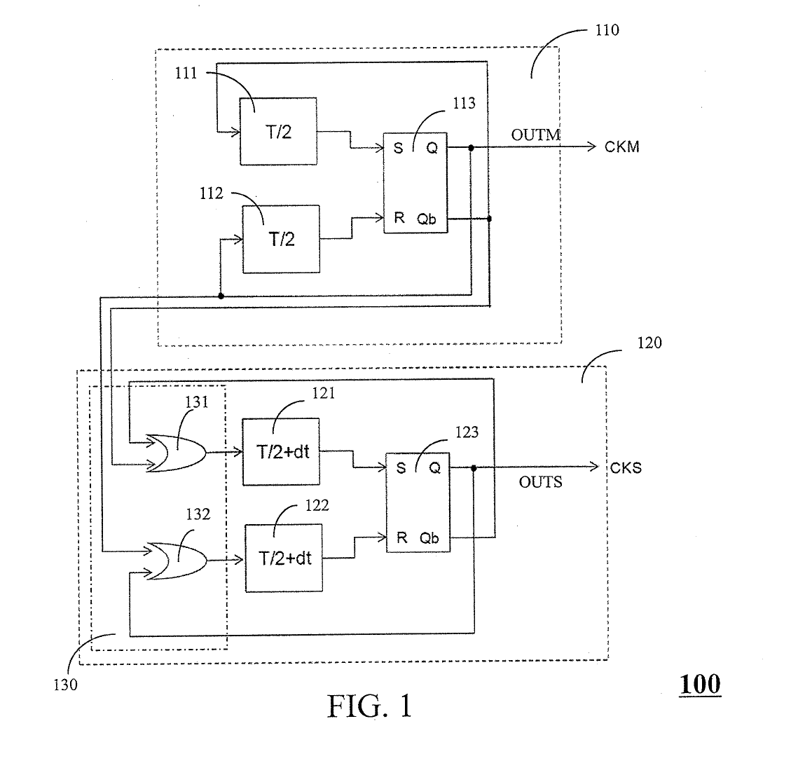

FIG. 1 schematically illustrates a block diagram of an oscillator or clock generator according to an embodiment of the invention.

According to this embodiment, the clock generator 100 comprises at least a master oscillator 110 and a slave oscillator 120. Of course, the clock generator 100 may comprise a plurality of slave oscillators, connected to the master oscillator, in cascade or in parallel one another. In FIG. 1, only one slave oscillator 120 is shown for sake of simplicity.

The master oscillator 110 comprises a first time delay stage 111 and a second time delay stage 112 each presenting a time delay of T/2 (T being one cycle of the a master clock signal CKM), the outputs of these stages being connected to respective input terminals of a first latch (or a flip-flop) 113, that is also included in the master oscillator 110. In the embodiment shown in FIG. 1, a Set-Reset (SR) latch (or flip-flop (F/F)) is used for the first latch 113, but the scope of the invention is not limited thereto. That is, depending on the implementation, other types of latch or flip-flop may be used. In particular, in the embodiment shown in FIG. 1, the time delay stages, 111 and 112, are respectively connected to a first or set terminal Sand a second or reset terminal R of the first latch 113 being a SR latch. The master oscillator 110 outputs a master clock signal CKM at its output terminal OUTM, which is connected to a first output terminal Q of the first latch 113. The first output terminal Q of the first latch 113 is feed-back connected to the second delay stage 112. A second output terminal Qb of the first latch 113 is feed-back connected to the first delay stage 111. The signal at the second terminal Qb is the complement of the signal at the first output terminal Q, which means that when Q is high Qb is low, and when Q is high, then Q is low.

The slave oscillator 120 comprises a third time delay stage 121 and a fourth time delay stage 122 each presenting a time delay of (T/2+dt), the outputs of these stages, 121 and 122, being connected to a second latch (flip-flop) 123. As for the master oscillator, a SR latch (or a SR FF) is used for the second latch 123, but the scope of the invention is not limited thereto. In particular, the time delay stages, 121 and 122, are respectively connected to a first or set terminal S and a second or reset terminal R of this second latch 123 being a SR latch. The slave oscillator 120 further comprises an input logic block 130 including a first logic gate 131 and a second logic gate 132. In the embodiment shown in FIG. 1, for example, the first logic gate 131 and the second logic gate 132 are OR gates, however different types of logic gate may be used for alternative embodiments. The slave oscillator 120 outputs a slave clock signal CKS at its output terminal OUTS, which is connected to a first output terminal Q of the second latch 123. The first output terminal Q of the second latch 123 is also connected to a first input terminal of the second logic gate 132, having a second input terminal connected to the first output terminal Q of the first latch 113 of the master oscillator 110. A second output terminal Qb of the second latch 123 is also feed-back connected to a first input terminal of the first logic gate 131, having a second input terminal connected to the second output terminal Qb of the first latch 113 of the master oscillator 110.

In this way, the master oscillator 110 generates the master clock signal CKM and the slave oscillator 120 generates the slave clock signal CKS that has a time shift equal to dt with respect to the master clock signal CKM and the same cycle period T as the master clock signal CKM. In particular, the first and second time delay stage 111, 112 may delay an input signal of T/2, T being one cycle period of the clock signal to be generated. The delayed signal is then provided to the first latch 113. Moreover, these two time delay stages cooperate to provide a sustained oscillation with period T.

More in particular, the first time delay stage 111 provides the low-to-high transitions of the master clock signal CKM through the first latch 113, while the second time delay stage 112 provides the high-to-low transitions of the master clock signal CKM through the first latch 113. The clock generator 100 may be also connected to a startup circuit not shown in FIG. 1.

Particularly, the delayed signal from the first time delay stage 111 may be provided to the set input S of the first latch 113, while the delayed signal from the second time delay stage 112 may be provided to the reset input R of the first latch 113. The first output terminal Q of the first latch 113 may be provided to the output terminal OUTM of the master oscillator 110. Then, the first output terminal Q of the first latch 113 may be provided to the second time delay stage 112, while the second output terminal Qb of the first latch 113 may be provided to the first time delay stage 111.

Moreover, the slave oscillator 120 comprises the third time delay stage 121 and the fourth time delay stage 122, each of them providing respectively the low-to-high and high-to-low transitions of the slave clock signal through the second latch 123. However, for the slave oscillator 120, the startup for the third time delay stage 121 is determined not by the second latch 123, but by a logic combination through the first logic gate 131 of the first latch 113 and the second latch 123 outputs. In the same way, startup for the fourth time delay stage 122 is determined not by the second latch 123, but by a logic combination through the second logic gate 132 of the outputs of the first latch 113 and the second latch 123.

Particularly, the delayed signal from the third delay stage 121 may be provided to the set input S of the second latch 123, while the delayed signal from the fourth time delay stage 122 may be provided to the reset input R of the second latch 113. The first output terminal Q of the second latch 123 may be provided to the output terminal OUTS of the slave oscillator 120. Then, the signal at the first output terminal Q of the second latch 123 may be provided to the input of the second logic gate 132 with the signal at the first output terminal Q of the first latch 113. In a similar way, the signal at the second output terminal Qb of the second latch 123 may be provided to the input of the first logic gate 131 with the signal at the second output terminal Qb of the first latch 113.

If the time delay for each of the third time delay stage 121 and the fourth time delay stage 122 is T/2+dt (being 0<dt<T/2), then the resulting slave clock signal CKS at the output terminal OUTS of the slave oscillator 120 has the same cycle period T as that of the master clock signal CKM at the output terminal OUTM of the master oscillator 110, but is shifted in phase by dt.

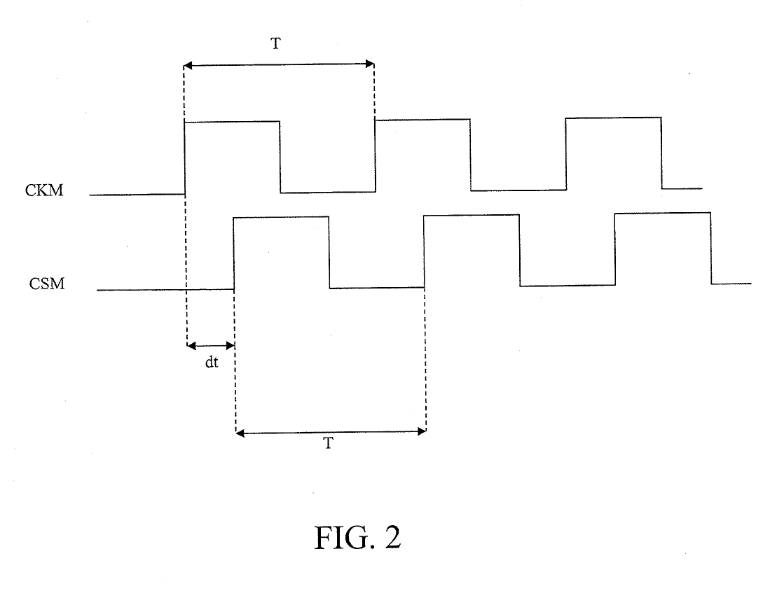

In this respect, FIG. 2 schematically shows a graph of the signals of the master oscillator 110 and the slave oscillator 120 according to FIG. 1. In this FIG. 2, it is easily understood that the time period for the master and slave clock signal is T, and the time delay or phase between these two clock signals is dt.

In an advantageous embodiment, all time delay stages 111, 112, 121, 122 may be matched circuits. The matched circuit means that the circuits are made by using matched components such as transistors, resistors, capacitors or others. For example matched transistors are transistors fabricated in the same area of a wafer, having a same orientation, and surrounded by same components. Any one of the time delay stages 111, 112, 121, 122 may include passive components and a charging reference current defining precise delay time and fixed ration between them.

According to an embodiment of the invention, the master and slave oscillators 110, 120 may be realized by a respective charge oscillator having a symmetrical structure and a common voltage reference.

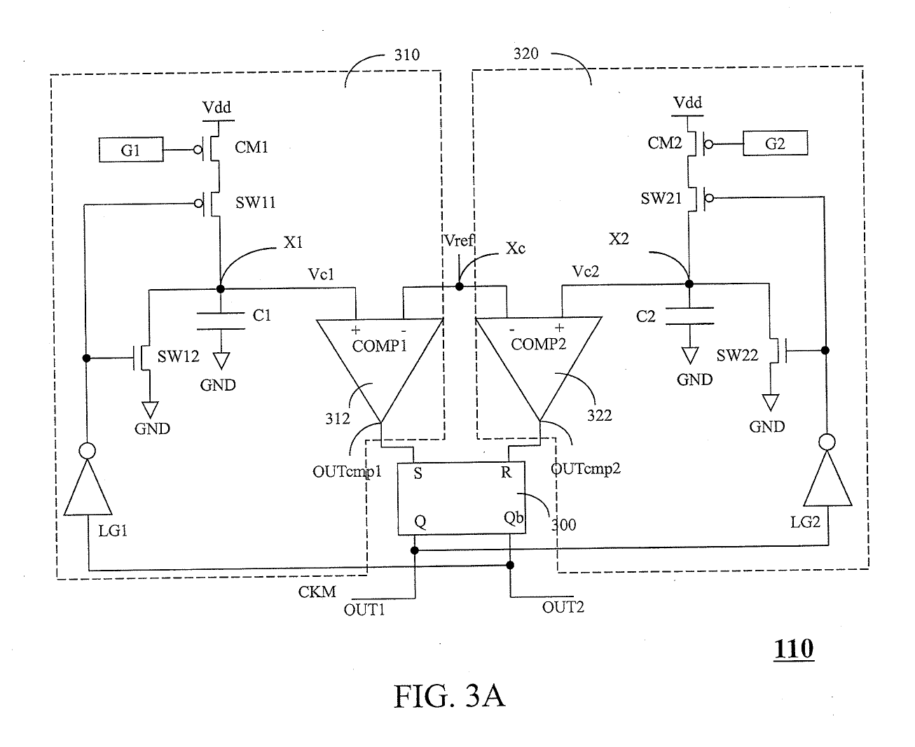

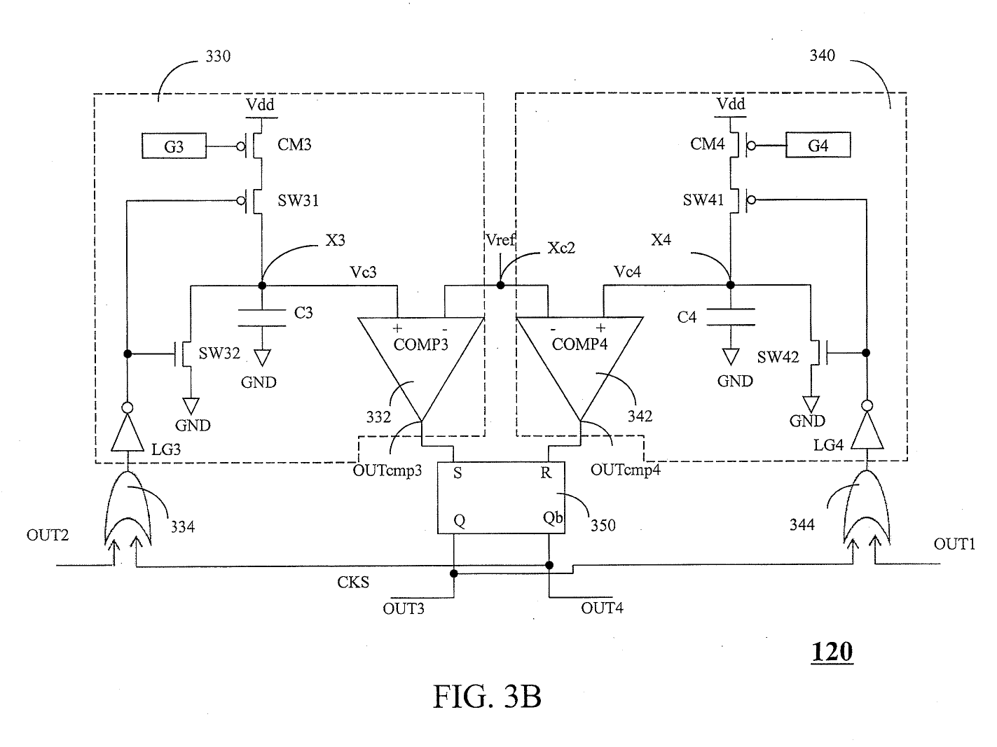

FIG. 3A schematically shows an embodiment of the master oscillator 110 of FIG. 1 implemented by using a charge oscillator.

The master oscillator 110 comprises a first or left module 310 and a second or right module 320 and is connected to a common voltage reference Vref. The first module 310 corresponds to the first time delay stage 111 of FIG. 1 and the second module 320 corresponds to the second delay stage 112 of FIG. 1. The master oscillator 110 also includes a first common latch 300, corresponding to the first latch 113 of FIG. 1. The first common latch 300 is for instance a SR latch but the scope of the invention is not limited thereto. That is, depending on the implementation, other types of latches or flip-flops may be used. In particular, the first common latch 300 has a first input or set terminal S, a second input or reset terminal R, a first output terminal Q and a second output terminal Qb. In this exemplary embodiment, the signal at the second output terminal Qb is the complement of the signal at the first output terminal Q, which means that when Q is high Qb is low, and when Q is high, then Q is low.

More in particular, the first module 310 comprises a first comparator COMP1 312, a first current mirror transistor CM1 biased by a first reference bias generator G1 to produce a substantially constant current, a first and a second switch transistor, SW11 and SW12, an inverter as a first logic gate LG1, as well as a first capacitance block including a first capacitor C1. More in particular, the first current mirror transistor CM1, the first switch SW11 and the first capacitor C1 are inserted, in series to each other, between a power supply voltage Vdd and ground GND, a first node X1 between the first switch SW11 and the first capacitor C1 being connected to a first non-inverting (+) input of the first comparator 312.

Moreover, the second switch SW12 is inserted between the first node X1 and ground GND. The first and second switches SW11 and SW12 have respective driving terminals connected to the second output terminal Qb of the first common latch 300 through the first logic gate LG1, being a NOT gate.

Furthermore, the first comparator 312 has a second inverting terminal (−) connected to a common node Xc receiving the common reference voltage Vref and an output terminal OUTcmp1 connected to the first input or set terminal S of the first common latch 300.

In a similar manner, the second module 320 comprises a second comparator COMP2 322, a second current mirror transistor CM2 biased by a second reference generator G2 to produce a substantially constant current, a third and a fourth switch, SW21 and SW22, an inverter as a second logic gate LG2, as well as a second capacitance block including a second capacitor C2. The second current mirror transistor CM2, the third switch SW21 and the second capacitor C2 are inserted, in series to each other, between the power supply voltage Vdd and ground GND, a second node X2 between the third switch SW21 and the second capacitor C2 being also connected to a first non-inverting (+) input of the second comparator 322. Moreover, the fourth switch SW22 is inserted between the second node X2 and ground GND. The third and fourth switches SW21 and SW22 have respective driving terminals connected to the first output terminal Q of the first common latch 300, through the second logic gate LG2, being a NOT gate. The first output terminal Q of the first common latch 300 is also connected to a first output terminal OUT1 providing the master clock signal CKM, while the second output terminal Qb of the first common latch 300 is connected to a second output terminal OUT2.

Furthermore, the second comparator 322 has a second inverting terminal (−) connected to the common node Xc receiving the common reference voltage Vref and an output terminal OUTcmp2 connected to the second input or reset terminal R of the first common latch 300. The second output terminal Qb of the first common latch 300 provides an inverted master clock signal.

FIG. 3B schematically shows an embodiment of the slave oscillator 120 of FIG. 1.

The slave oscillator 120 has a basic structure being similar to the master oscillator 110 of FIG. 3A.

The slave oscillator 120 then comprises a first or left module 330 and a second or right module 340 and is connected to a second common voltage reference Vref. The first module 330 corresponds to the third time delay stage 121 of FIG. 1 and the second module 340 corresponds to the fourth delay stage 122 of FIG. 1. The slave oscillator 120 also includes a second common latch 350, corresponding to the second latch 123 of FIG. 1 and being for instance a SR latch but the scope of the invention is not limited thereto. That is, depending on the implementation, other types of latch or flip-flop may be used. In particular, the second common latch 350 has a first input or set terminal S, a second input or reset terminal R, a first output terminal Q and a second output terminal Qb. In this exemplary embodiment, the signal at the second output terminal Qb is the complement of the signal at the first output terminal Q, which means that when Q is high Qb is low, and when Q is high, then Q is low. Moreover, the first output terminal Q of the second common latch 350 is connected to a third output terminal OUTS providing the slave clock signal CKS and the second output terminal Qb of the second common latch 350 is connected to a fourth output terminal OUT4.

More in particular, the first module 330 comprises a third comparator COMP3 332, a third current mirror transistor CM3 connected to a third reference bias generator G3 to produce a substantially constant current, a fifth and a sixth switch, SW31 and SW32, a third logic gate LG3, in particular a NOT gate (inverter), as well as a third capacitance block including a third capacitor C3. More in particular, the third current mirror transistor CM3, the fifth switch SW31 and the third capacitor C3 are inserted, in series to each other, between a power supply Vdd and ground GND, a third node X3 between the third switch SW31 and the third capacitor C3 being connected to a first non inverting (+) input of the third comparator 332. Furthermore, the third comparator 332 has a second inverting terminal (−) connected to a second common node Xc2 receiving the second common reference voltage Vref, being for instance equal to the common reference voltage applied to the master oscillator 110, and an output terminal OUTcmp3 connected to the first input or set terminal S of the second common latch 350.

In a similar manner, the second module 340 comprises a fourth comparator COMP4 342, a fourth current mirror transistor CM4 connected to a fourth reference bias generator G4 to produce a substantially constant current, a seventh and a eight switch, SW41 and SW42, a fourth logic gate LG4, in particular a NOT gate, as well as a fourth capacitance block including a fourth capacitor C4. The fourth current mirror transistor CM4, the seventh switch SW41 and the fourth capacitor C4 are inserted, in series to each other, between the power supply Vdd and ground GND, a fourth node X4 between the seventh switch SW41 and the fourth capacitor C4 being connected to a first non inverting (+) input of the fourth comparator 342. Moreover, the eight switch SW42 is inserted between the fourth node X4 and ground GND.

Furthermore, the fourth comparator 342 has a second inverting terminal (−) connected to the second common node Xc2 receiving the second common reference voltage Vref, being for instance equal to the common reference voltage applied to the master oscillator 110, and an output terminal OUTcmp4 connected to the second input or reset terminal R of the second common latch 350.

Moreover, the slave oscillator 120 comprises a first logic gate 334 connected to the third logic gate LG3 of the left module 330 and a second logic gate 344 connected to the fourth logic gate LG4 of the right module 340. The first and second logic gates 334 and 344 are for instance OR gates that are equivalent to the OR gates 131 and 132 of FIG. 1.

More in particular, the first logic gate 334 has a first input terminal connected to the second output terminal Qb of the second common latch 350, i.e. to the fourth output terminal OUT4, a second input terminal connected to the second output terminal OUT2 of the master oscillator 110 and an output terminal connected to the driving terminals of the fifth and sixth switches, SW31 and SW32 through the third logic gate LG3. More in particular, the fifth switch SW31 comprises a PMOS transistor and the sixth switch SW32 comprises an NMOS transistor.

In a similar manner, the second logic gate 344 has a first input terminal connected to the first output terminal Q of the second common latch 350, i.e. to the third output terminal OUTS, a second input terminal connected to the first output terminal OUT1 of the master oscillator 110 and an output terminal connected to the driving terminals of the seventh and eight switches, SW41 and SW42 through the fourth logic gate LG4. More in particular, the seventh switch SW41 comprises a PMOS transistor and the eighth switch SW42 comprises an NMOS transistor.

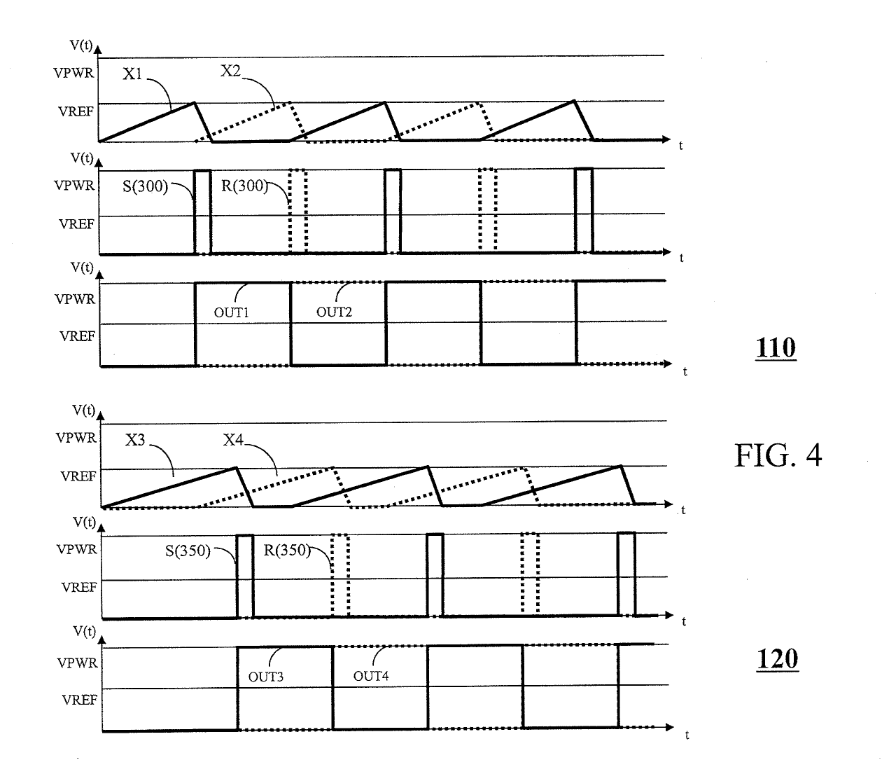

The working of the master oscillator 110 of FIG. 3A is now described with reference also FIG. 4. The first switch SW11 and the second switch SW12 may be switched by the second output terminal Qb of the first common latch 300, in turn connected to the second output terminal OUT2 and duly inverted by the first logic gate LG1. The capacitor C1 of the first capacitance block is charged by a current flowing from the first switch SW11 and discharged by a current drawn by the second switch SW12.

Moreover, the third switch SW21 and the fourth switch SW22 may be switched by the first output terminal Q of the first common latch 300, in turn connected to the first output terminal OUT1 and duly inverted by the second logic gate LG2. The capacitor C2 of the second capacitance block is charged by a current flowing from the third switch SW21 and discharged by a current drawn by the fourth switch SW22.

In this way, the signal at the second output terminal Qb of the first common latch 300 (being the opposite of the signal at the first output terminal Q) is fed back to the first and second switches, SW11 and SW12, to control the current provided by the first current mirror transistor CM1 and thus activate the charge and/or discharge of the capacitor C1 of the first capacitance block and the signal at the first output terminal Q of the first common latch 300 (being the opposite of the signal at the second output terminal Qb) is fed back to the third and fourth switches, SW21 and SW22, to control the current drawn by the second current mirror transistor CM2 and thus activate the charge and/or discharge of the capacitor C2 of the second capacitance block.

The charge and discharge of the capacitor C1 of the first capacitance blocks is repeated periodically, thus generating a period clock signal, the master clock signal, at the first output terminal Q of the first common latch 300, i.e. at the first output terminal OUT1. In other words, the signal transition propagates starting from the first node X1, to the first comparator 312, the first input terminal S of the first common latch 300, and from the first output terminal Q of the first common latch 300, to the third switch SW21 and the capacitor C2 of the second capacitance block i.e. to the second node X2.

In a similar manner, the charge and discharge of the capacitor C2 of the second capacitance block is repeated periodically, thus generating a period clock signal, an inverted master clock signal, at the second output terminal Qb of the first common latch 300, i.e. at the second output terminal OUT2.

In other words, the signal transition propagates starting from the second node X2, to the second comparator 322, the second input terminal R of the first common latch 300, and from the second output terminal Qb of the first common latch 300, to the first switch SW11 and the capacitor C1 of the first capacitance block i.e. to the first node X1.

The capacitor C1 of the first capacitance block and the capacitor C2 of the second capacitance block may be equal and matched in size, if the duty cycle of the output signal of the master oscillator 110 needs to be 0.5. Moreover, the current provided by the two current generators G1 and G2 may be equal and the current mirror transistors CM1 and CM2 matched in size, if the duty-cycle of the output signal of the master oscillator 110 needs to be 0.5. Furthermore, the size ratio between the capacitor C1 of the first capacitance block and the capacitor C2 of the second capacitance block, as well as the current ratio of the first current mirror transistor CM1 and the second current mirror transistor CM2 may be configured to obtain different duty cycles.

Moreover, the first current mirror transistor CM1 and the second current mirror transistor CM2 may be output stages of circuits mirroring and scaling a reference current provided by a current generator, G1 and G2 respectively, for instance being a current showing a limited variation with temperature and power supply.

In essence, the first comparator 312 and the second comparator 322 respectively sense the voltage value at the first node X1 and the second node X2, and provide respective output signals when the first node X1 and the second node X2 are higher than the common reference voltage Vref. The reference voltage Vref may also be a voltage having a limited variation with temperature and power supply.

Being the output terminals, OUTcmp1 and OUTcmp2, of the first and second comparators, 312 and 322, coupled respectively to the set and reset input terminals, S and R, of the first common latch 300, being a SR latch, a master clock signal CKM is provided by the master oscillator 110 at the first output terminal OUT1, being connected to the first output terminal Q of the first common latch 300. It is easily understood by a skilled person in the art that also the signal at the second output terminal OUT2, being connected to the second output terminal Qb of the first common latch 300 may provide an inverted master clock signal, being a complement of the clock signal at the first output terminal OUT1.

Due to the corresponding structure, the working of the slave oscillator 120 is similar to the one of the master oscillator 110 and a slave clock signal CKS is provided at the third output terminal OUT3 and, in an inverted form, at the fourth output terminal OUT4

It should be noted, however, that the capacitance of the third capacitor C3 and of the fourth capacitor C4 as well as the size of the third current mirror transistor CM3 and of the fourth current mirror transistor CM4 of the slave oscillator 120 might be different with respect to their counterparts in the master oscillator 110, i.e. the first and second capacitors C1 and C2 and the first and second current mirror transistors CM1 and CM2.

More in particular, the ratio between the first capacitor C1 and the third capacitor C3 and the ratio between the second capacitor C2 and the fourth capacitor C4 may be chosen to define the time shift between the master clock signal CKM at the first output terminal OUT1 and the slave clock signal CKS at the third output terminal OUT3. Also, the ratio between the mirror factor of the first current mirror transistor CM1 and the third current mirror transistor CM3 and the ratio between the mirror factor of the second current mirror transistor CM2 and the fourth current mirror transistor CM4 can be chosen to define the time shift between the master clock signal CKM and the slave clock signal CKS.

The time shift between the master clock signal CKM and the slave clock signal CKS is obtained by slowing the ramp voltage applied to the capacitors C3 and C4 of the slave oscillator 120 with respect to the ramp voltage applied to capacitors C1 and C2 of the first and second capacitive blocks of the master oscillator 110.

In a general form, a slower ramp for the charging of the third node X3 of the slave oscillator 120 than the ramp for the charging the first node X1 of the master oscillator 110 may be obtained as follows:

a. by having a lower charging current applied to the third capacitor C3, the capacitance value of this third capacitor C3 being the same of that of the corresponding first capacitor C1 of the master oscillator 110;
b. by using a same current for the first and third capacitors, C1 and C3, the latter having a bigger capacitance value;
c. by combining the previous two modes, i.e. using a lower current and a bigger capacitance for the third capacitor C3 than for the first capacitor C1.

The above can be also applied for obtaining a slower ramp for the charging of the fourth node X4 of the slave oscillator 120 than a ramp for the charging of the second node X2 of the master oscillator 119, the second and fourth capacitors, C2 and C4 being at stake.

Alternatively, the time shift between the master clock signal CKM and slave clock signal CKS could be obtained, employing the same ramp voltage, by changing the value of the voltage reference Vref, the value of this voltage reference Vref for the slave oscillator 120 being higher than the one for the master oscillator 120, thus making the second common latch 350 switching with delay with respect to the first common latch 300.

For example, if a time shift of T/4 is needed between the master clock signal CKM of the master oscillator 110 and the slave clock signal CKS of the slave oscillator 120, then the following conditions may be chosen:

(the mirror factor of the first current mirror transistor CM1)/(the mirror factor of the third current mirror transistor CM3)=1

(the mirror factor of the second current mirror transistor CM2)/(the mirror factor of the fourth current mirror transistor CM4)=1

the capacitance ratio C3/C1=1.5

the capacitance ratio C4/C2=1.5

the same voltage reference Vref for both master and slave oscillators, 110 and 120.

In the above condition, since the mirror factors are same but the ratios of the capacitance values are different and the time required to charge a capacitor is proportional to the capacitance value, indeed, the time required for charging the capacitors C3 and C4 in the slave oscillator 120 is longer than that for charging the capacitors C1 and C2 in the master oscillator 110. In this way, the slave clock signal CKS at the output of the slave oscillator 120 has a time shift with respect to the master clock signal CKM at the output of the master oscillator 110.

In another example, different conditions may be chosen to obtain a same amount of time shift. The conditions maybe as follows:

(the mirror factor of the first current mirror transistor CM1)/(the mirror factor of the third current mirror transistor CM3)=1.5

(the mirror factor of the second current mirror CM2)/(the mirror factor of the fourth current mirror transistor CM4)=1.5

the capacitance ratio C3/C1=1

the capacitance ratio C4/C2=1

the same voltage reference Vref for both master and slave oscillators, 110 and 120.

In the above condition, since the ratios of the capacitance values are the same but the mirror factors are different and the time required to charge a capacitor is inversely proportional to the charging current, the time required for charging the capacitors C3 and C4 in the slave oscillator 120 is longer than that for charging the capacitors C1 and C2 in the master oscillator 110. Then, also in this case, the slave clock signal CKS at the output of the slave oscillator 120 has a time shift with respect to the master clock signal CKM at the output of the master oscillator 120. The amount of the time shift is the same as that of the previous condition.

To explain the operation of the clock generator 100 more specifically, making reference to FIGS. 3A and 3B, when the master oscillator 110 triggers a falling edge for the output signal at the first output terminal Q of the first common latch 300, i.e. the first output terminal OUT1, that corresponds to a rising edge for the output signal at the second output terminal Qb of this first common latch 300, i.e. the second output terminal OUT2, then the third current mirror transistor CM3 of the slave oscillator 120 allows a current charging the third capacitor C3 by turning on the fifth switch SW31. The third node X3 then starts rising. If one of the aforementioned design choices is made, the charging of the third node X3 in the slave oscillator 120 is 50% slower than the charging for the corresponding first node X1 in the master oscillator 110. When the third node X3 reaches the value of the reference voltage Vref, the third comparator 332 rises the signal at the set input terminal S of the second common latch 350 and the first output terminal Q of the second common latch 350, i.e. the third output terminal OUT3, is then set.

A rising edge of the output signal at the first output terminal Q of the second common latch 350, i.e. of an output signal Vout3 at the third output terminal OUT3, corresponds to a falling edge of the output signal at the second output terminal Qb of the second common latch 350, i.e. of an output signal Vout4 of the fourth output terminal OUT4, the charging of the third node X3 being thus stopped through the first logic gate 334 and the discharging of the third node X3 being accomplished through the sixth switch SW32.

In fact, the first logic gate 334 in this phase has both its input terminals receiving the signals of the second and fourth output terminals, OUT2 and OUT4, which are at a low logic level. Therefore, being the first logic gate 334 a OR gate, its output would then lower at a low logic level, and the output of the inverter LG3 would then raise to high logic level, in this way turning off the fifth switch SW31 (which comprises a PMOS transistor) thus stopping the charging of the third node X3, and, at the same time, turning on the sixth switch SW32 (which comprises an NMOS transistor) thus discharging to ground the third node X3.

In the same way, when the master oscillator 110 triggers a rising edge of the output signal Vout1 at the first output terminal OUT1, that corresponds to a falling edge of the output signal Vout2 at the second output terminal OUT2, then the fourth current mirror transistor CM4 of the slave oscillator 120 allows a current charging the fourth capacitor C4 by turning on the seventh switch SW41. The fourth node X4 then starts rising. Again, the charging of the fourth node X4 in the slave oscillator 120 is 50% slower than the charging of the corresponding second node X2 in the master oscillator 110.

When the fourth node X4 reaches the value of the common reference voltage Vref, the fourth comparator 342 rises the signal at the reset input R of the second common latch 350 and the second output terminal Qb of the second common latch 350 is set. A rising edge of the output signal at the second output terminal Qb of the second common latch 350, i.e. of the output signal Vout4 at the fourth output terminal OUT4, corresponds to a falling edge of the output signal at the first output terminal Q of the second common latch 350, i.e. of an output signal Vout3 at the third output terminal OUT3, the charging of the fourth node X4 being then stopped through the second logic gate 344.

In fact, the second logic gate 344 in this phase has both its input terminals receiving the signals of the first and third output terminals, OUT1 and OUT3, which are at a low logic level. Therefore, being the second logic gate 344 a OR gate, its output would then lower at a low logic level, and the output of the inverter LG4 would then raise to high logic level, in this way turning off the seventh switch SW41 (which comprises a PMOS transistor) thus stopping the charging of the fourth node X4, and, at the same time, turning on the eight switch SW42 (which comprises an NMOS transistor) thus discharging to ground the fourth node X4.

It is noted that a rising edge of the output signal Vout2 at the second output terminal OUT2, that corresponds to a falling edge of the output signal Vout1 at the first output terminal OUT1, initiates the charging of the third node X3. Therefore, the third node X3 has already started ramping when the output signal Vout3 at the third output terminal OUT3 rises and the output signal Vout4 at the fourth output terminal OUT4 falls. It is also noted that a rising edge of the output signal Vout1 at the first output terminal OUT1, that corresponds to a falling edge of the output signal Vout2 at the second output terminal OUT2, initiates the charging of the fourth node X4. Therefore, the fourth node X4 has already started ramping when the output signal Vout3 at the third output terminal OUT3 rises and the output signal Vout4 at the fourth output terminal OUT4 falls.

FIG. 4 schematically shows a time diagram of a clock generator comprising the master oscillator 110 of FIG. 3A and the slave oscillator 120 of FIG. 3B.

The diagram shows the pattern of the voltages of the first, second, third and fourth nodes X1, X2, X3 and X4, the voltages at the input terminals S and R of the common latches 300 and 350, and the voltages at the output terminals OUT1, OUT2, OUTS and OUT4. It is noted that the time shift between the output signal Vout3 at the third output terminal OUTS and the output signal Vout1 at the first output terminal output OUT1 as well as the time shift between the output signal Vout4 at the fourth output terminal OUT4 and the output signal Vout2 at the second output terminal OUT2 is constant and equal to T/4 after a short latency startup time.

In particular, the signal at the first output terminal OUT1 is the master clock signal CKM, while the signal at the third output terminal OUT3 is the slave clock signal CKS. It is noted that the slave clock signal CKS has a same waveform but is shifted with respect to the master clock signal CKM. In particular, the voltage patterns of the input terminals S and R of the first common latch 300 show that when the voltage at the first node X1 reaches the value of the common voltage reference Vref, the corresponding first comparator 312 switches at the set terminal S of the first common latch 300 and raises the master clock signal CKM and when the voltage at the second node X2 reaches the value of the common voltage reference Vref, the reset terminal R of the first common latch 300 switches and lowers the master clock signal CKM. The voltage patterns at the third and fourth nodes, X3 and X4, also show that a slower ramp is needed, being for instance 1.5 times slower than the one for the first and second nodes, X1 and X2, the generation of the slave clock signal CKS being provided in an analogous manner than the generation of the master clock signal CKM.

The first, second, third and fourth capacitors, C1, C2, C3 and C4, as well as the first, second, third and fourth current mirror transistors, CM1, CM2, CM3 and CM4, may have a layout comprising interleaved structures in order to improve the respective matching and achieve greater accuracy in both duty cycle and time shift. The first, second, third and fourth comparators, 312, 322, 332 and 342, may also be drawn as matched structures to match offset and achieve a better precision for the clock generator 100 as a whole. With such a design, the time shift accuracy relies upon the matching between the components of the master and slave oscillators. This matching can be very high for integrated electronic circuits. Moreover, shift time is highly insensitive to the power supply reference and the temperature variation being tied to the period time of these precise oscillators. The architecture as described allows an extremely flexible configurability for the time shift.

In particular, if the time shift between the two oscillators is a fixed design parameter and does not need to be changed then no extra configurations are needed to adjust the time shift if clock period is varied. In fact, because of the component ratios, the time shift over period ratio will be maintained when a different period value is selected.

Meanwhile, combining more than one slave oscillators, it is possible to make a clock generator which generates more than one slave clock signals, each slave clock signal having a different phase.

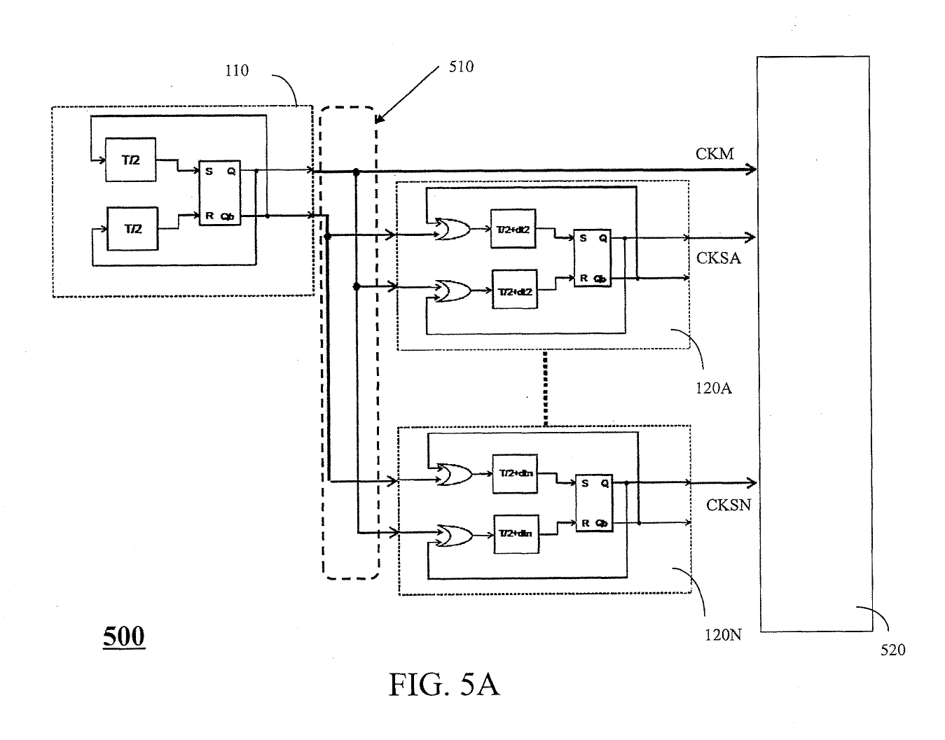

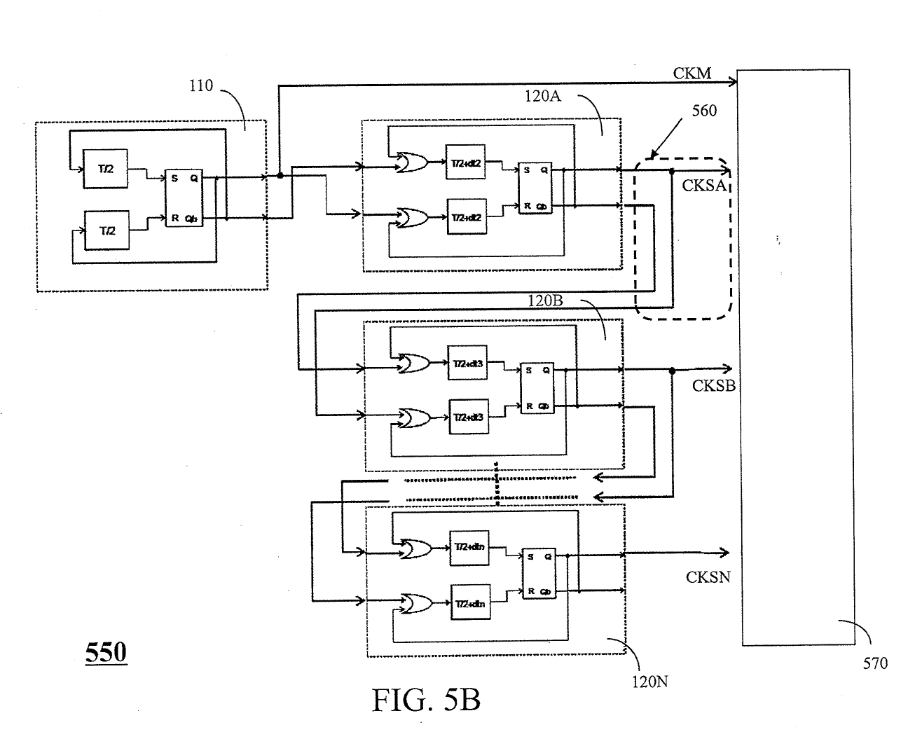

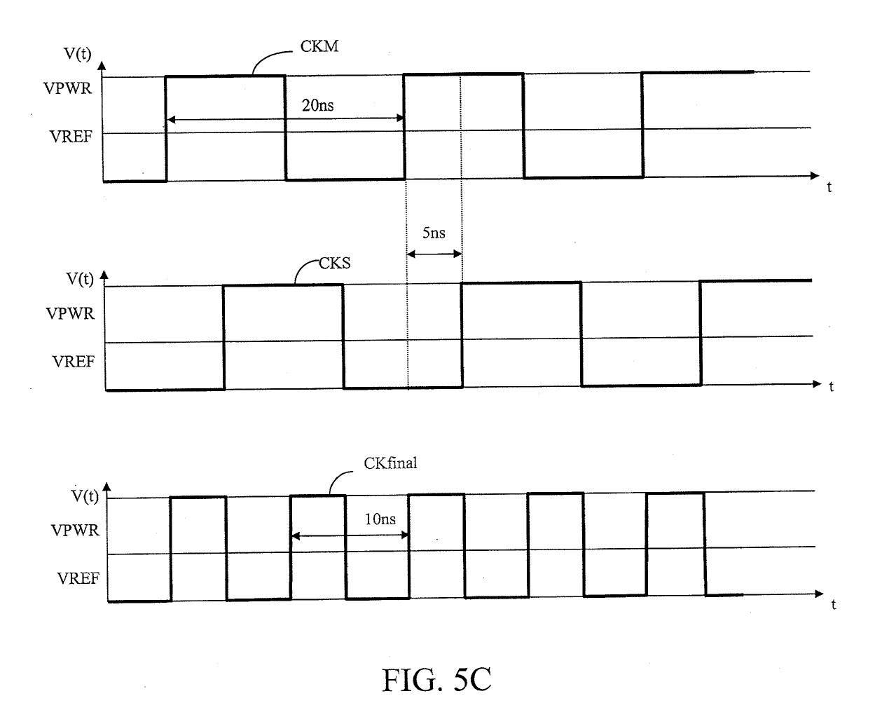

FIG. 5A schematically shows a clock generator 500 according to a second embodiment of the invention, that includes more than one slave oscillators 120A . . . 120N connected in parallel to each other such that each of the slave oscillators 120A-120N receives true and complementary the master clock signals CKM.

More in particular, the clock generator 500 comprises a master oscillator 110 and the plurality of slave oscillators 120A . . . 120N. Each slave oscillator 120 is connected with the master oscillator in a direct manner, in a connection area indicated by 510. As an example, if four clock signals are needed with a time shift of T/8 among them, then a first slave oscillator 120A may charge its capacitors with a slope that is 1/(1+¼) with respect to the master oscillator 110. A second slave oscillator 120B would then need to charge its capacitors with a slope of 1/(1+ 2/4), i.e. 1/(1+½) with respect to the master oscillator 110. A third slave oscillator 120C would also need to charge its capacitors with a slope of 1/(1+¾) i.e. 1/(1+½+¼) with respect to the master oscillator 110.

In fact, considering that the master oscillator 110 needs to charge its capacitors in T/2, if a time shift of T/8 is required among the master and each of slave oscillators, 110 and 120, then the first slave oscillator 120A needs to charge its capacitors in T/2+T/8=5T/8, the second slave oscillator 120B needs to charge its capacitors in T/2+T/4 and the third oscillator 120C needs to charge its capacitors in T/2+T/4+T/8.

A logic block 520 may be also connected to the outputs of the master oscillator and of the slave oscillators in order to combine the outputted clock signals.

The charging time of each of the slave oscillators 120A . . . 120N can be adjusted as explained before.

FIG. 5B schematically shows a clock generator 550 according to a third embodiment of the invention, that includes more than one slave oscillator 120A, 120B . . . 120N connected in series to each other such that the slave oscillators 120A-120N are connected in cascade fashion so that the slave clock signal of the preceding one of the slave oscillators is supplied to the succeeding one thereof with the first stage 120A being supplied with the master clock signal.

More in particular, the clock generator 550 comprises a master oscillator 110 and the plurality of slave oscillators 120A, 120B . . . 120N, the slave oscillators being connected to one another, in a connection area indicated by 560 for a first slave oscillator 120A connected to a second slave oscillator 120B. In this case, if four clock signals are needed with a time shift of T/8 among them, the clock generator 550 can be designed in such a way that each of the slave clock signal may have a same delay of a slope of 1/(1+¼) with respect to the previous one. The output clock signal of each slave oscillator will be delayed sequentially with respect to the previous slave oscillator. In particular, a clock signal outputted by a first slave oscillator 120A would have a shift with reference to the master clock signal while the clock signal outputted by a second slave oscillator 120B would have a shift with reference to the clock signal outputted by the first slave oscillator 120A, and so on.

A logic block 570 may be also connected to the outputs of the master oscillator and of the slave oscillators in order to combine the outputted clock signals.

Also in this case, the charging time of each of the slave oscillators 120A . . . 120N can be adjusted as explained before.

FIG. 5C schematically shows a time diagram according to the fourth embodiment of the present invention, which is retrieved by applying ex-or operation on the outputs of master and slave clock signals generated respectively by the master and slave clock generators described so far. A final clock signal CKfinal having higher frequency than the mast clock signal is thus derived.

More specifically, the final clock signal CKfinal is simply obtained by EX-OR combining a master clock signal CKM and a slave clock signal CKS, the final clock signal CKfinal thus having a higher frequency with respect to the master clock signal CKM. In particular, it is to be noted that the so obtained high frequency clock signal is stable and very precise.

For example, by using a master oscillator 110 and a slave oscillator 120 with a period of 20 ns and a time shift of T/4, i.e. 5 ns between them, the final clock signal CKfinal with a period of 10 ns could be obtained, as shown in FIG. 5C.

Alternatively, four slave oscillators with a period of 40 ns and a time shift of T/8, i.e. 5 ns may be employed in an architecture as the clock generator 550 of FIG. 5B, and the slave clock signals at the outputs of the slave oscillators may be combined by a simple logic circuit 570 to obtain a final clock signal with a period of 10 ns.

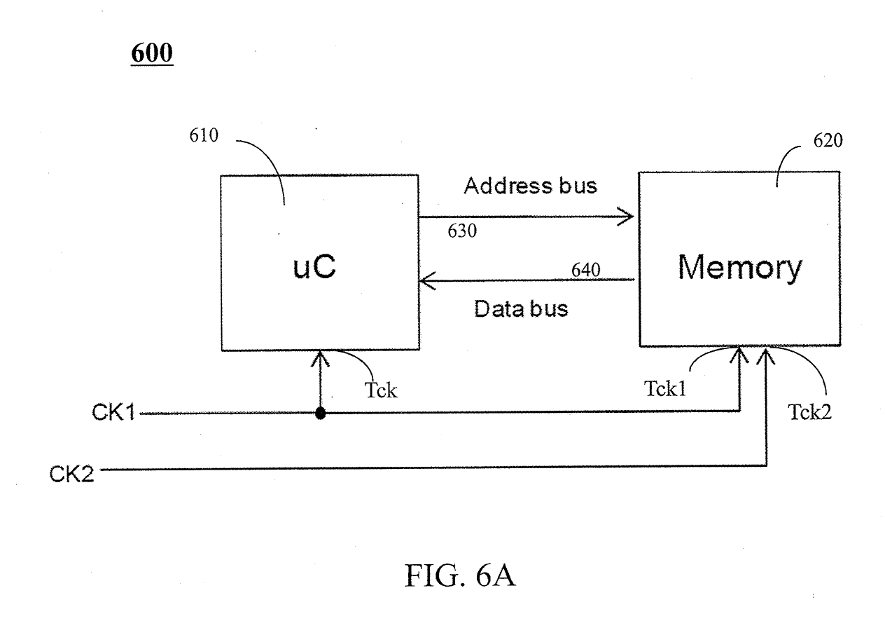

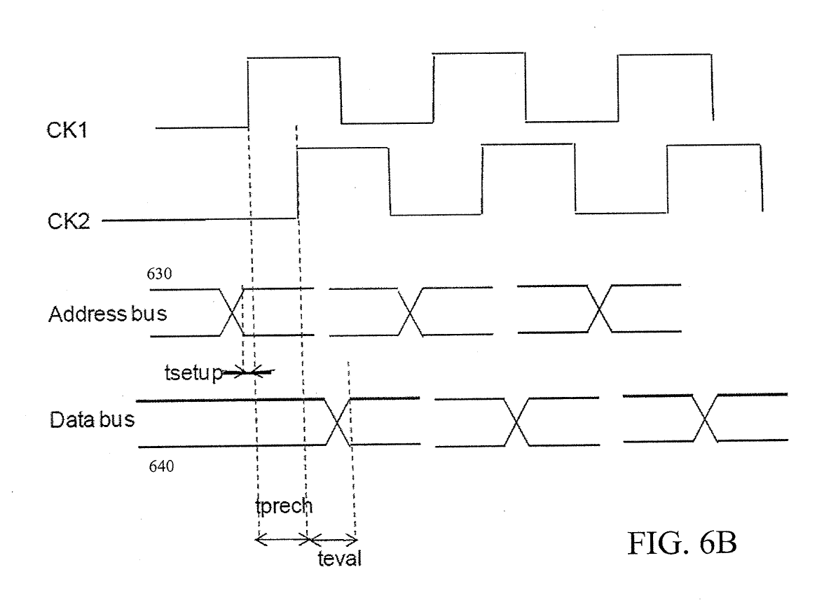

FIG. 6A schematically shows a block diagram indicative of, as a fifth embodiment of the invention, an architecture comprising at least a microprocessor and a memory which require different clock signals, in particular a first and a second clock signal, CK1 and CK2.

More in particular, the architecture 600 comprises a micro-controller uC (or any other type controller such as a memory controller) 610 and a memory 620, connected to each other by means of an address bus 630 and a data bus 640. The architecture 600 also comprises a first and a second clock signal, CK1 and CK2 respectively. More in particular, the first clock signal CK1 is connected to a clock terminal Tck of the micro-controller 610 and to a first clock terminal Tck1 of the memory 620, while the second clock signal CK2 is connected to a second clock terminal Tck2 of the memory 620. In this architecture, the micro-controller 610 retrieves data from the memory 620, or store data into the memory 620. The clock signals CK1 and CK2 are generated respectively by the master clock generator and the slave clock generators described above in connection with FIGS. 1-5B

FIG. 6B schematically shows a time diagram of the clock signals CK1, CK2 and of the buses 630, 640 when the microprocessor 610 retrieves data from memory 620 according to the architecture of FIG. 6A.

More in particular, the micro-controller 610 asserts address information on the address bus 630 with a setup delay tsetup with respect to a rising edge of the first clock signal CK1. The uC 610 may issue other control signals (not shown) to read out data from the memory 620. Between the rising edge of the first clock signal CK1 and a rising edge of the second clock signal CK2, the address is decoded internally of the memory 620, and all the bit-lines (not shown) in the memory 620 to be read are precharged in a time delay tprech. Then, after the rising edge of the second clock signal CK2, the evaluation phase of the memory 620 is initiated and it outputs a valid data on the data bus 640 after the time delay teval. Thus, two clock signals CK1 and CK2 are needed with different phases, in particular with a precise phase-shift between them. These two clock signals may be obtained by a clock generator according to the above embodiments of the present disclosure.

Some applications also require that the oscillation period is adjusted. Such adjustment may be done during a testing phase of a memory device. In this case, in order to adjust the oscillation period, driving signals of the clock generator may be used on the basis of configuration values already stored.

In particular, driving signals of the clock generator are input digital signals in the clock generator block, being used for different purposes, such as to adjust the clock period and/or the phase shift between the master and slave oscillators. According to FIGS. 6A and 6B, CK1=CKM and CK2=CKS are the two output clock signals of the generator block, while the input driving signals are for example provided by the date bus and are then used to adjust phase shift between the clock signals CKM and CKS as above explained.

In a similar way, these input driving signals may be employed to configure or finely adjust the oscillation period of the clock signals CKM and CKS. In this case, both master and slave oscillators need to be provided with a respective configuration circuit.

Alternatively a subset of the signal bus lines can be used to adjust the oscillation period and another subset can be used to adjust the phase shift.

It should be remarked that these driving signals, also indicated as “configuration signals”, are typical in flash memory devices. They are used to configure or finely adjust on-board analog circuits. In particular, these driving signals deliver information stored in fuses, or stored in a specific flash memory area and can be written during a testing phase of the flash memory, being usually loaded at the power-on stage.

For example, considering that a 10 ns shift between the master and slave clock signals is needed, this shift corresponds to the digital code 010 when using a driving or “configuration” signal bus of 3 bits (but in general it can be of any length).

During a test-mode phase, the code 010 should be thus written in a corresponding area of the flash memory device through the data and/or configuration bus. In this way, this code will be read at every flash memory power-up, stored in specific latches or flip-flops and delivered to the corresponding analog circuit (in this case the slave oscillator) by means of the driving or “configuration” bus lines.

Suitable driving signals may be applied to the clock generator according to the present disclosure in order to configure the time-shift between the provided master and slave clock signals.

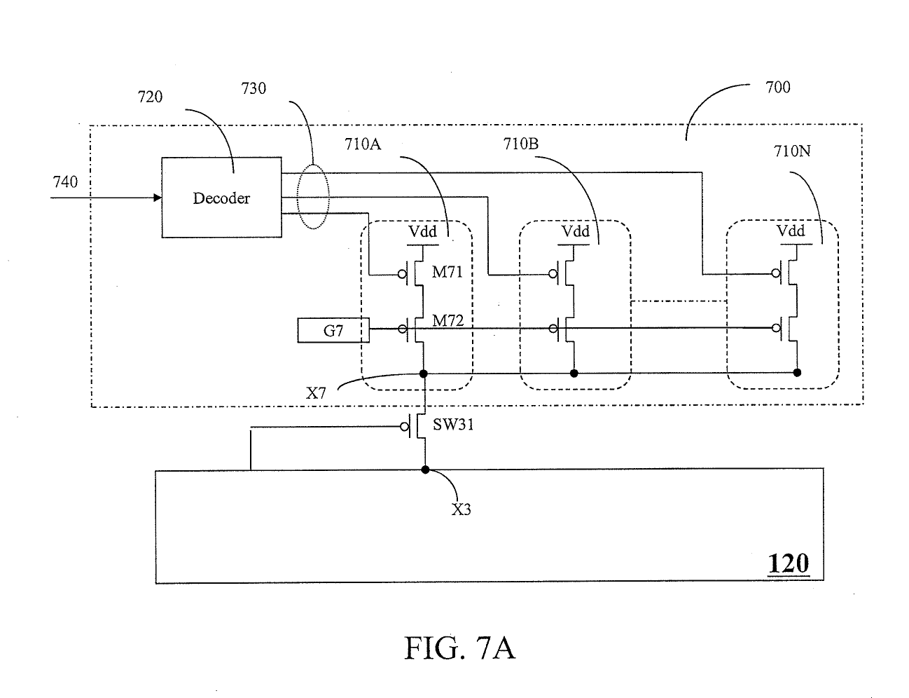

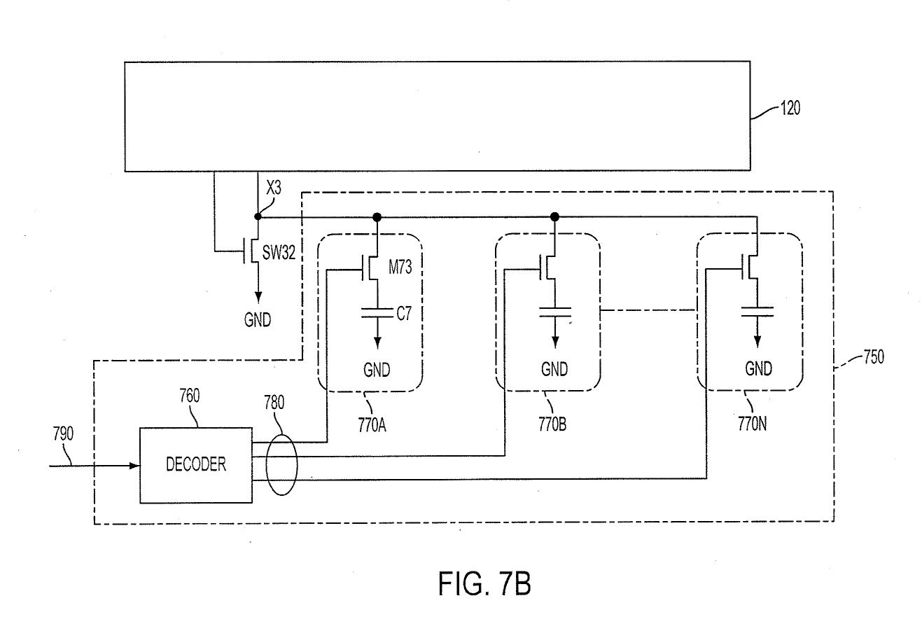

FIG. 7A schematically shows a configurable current mirror 700, that may be used in place of current circuit of G3 and CM3 in the slave oscillator 120 as shown in FIG. 3B, according to another embodiment of the invention. The output of the current mirror 700 is thus connected to the switch transistor SW31.

The current mirror 700 comprises a decoder 720 connected to N input lines of an input bus 740 as configuration data, the decoder thus including an output bus 730 of 2^{N} control lines. A control unit (not shown) or the uC 610 may provide the configuration data to the decoder 720 through the input bus 740. The current mirror 700 also comprises a plurality of switch blocks, 710A . . . 710N, each inserted between a supply voltage reference Vdd and a common node X7, which is in turn connected to the third node X3 of the slave oscillator 120 through the fifth switch SW31. In particular, each switch block 710 comprises a switching transistor M71 and a mirror-connected transistor M72 connected in series to each other between the supply voltage reference Vdd and the common node X7, the switching transistor M71 having a control or gate terminal connected to one control line of the output bus 730. Moreover, the mirror-connected transistors M72 of the switch blocks 710A . . . 710N have their control or gate terminals connected in common to a bias generator G7. Each transistor M72 thus produces a substantially constant current.

It should be noted that the decoder 720 selectively set or reset each of the 2^{N} control lines of the output bus 730 to enable selected one or ones of the switch blocks 710A . . . 710N. The mirror-connected transistor M72 of the selected switch block controls the amount of current flowing therethrough, such current amount being controlled by the bias circuit G7. That is to say, the mirror-connected transistor M72 of each switch block 710A . . . 710N is a current mirror that allows a current flowing whose amount depends on the mirror factor of the second switching transistor M72 indeed.

The switching transistor M71 is a configuration switch which switches on or off the current flowing through itself, driven by the configuration data outputted by the decoder 720 on the control lines of the output bus 730. In this way, based on the configuration data provided by the decoder 720, the current flowing to the common node X7 and thus to the third node X3 of the slave oscillator 120 can be controlled by the configurable current mirror 700.

In essence, the configurable current mirror 700 allows a selection of the time shift between the master and slave clock signals by changing a mirroring factor and thus the current provided to the slave oscillator 120.

In order to obtain a proper time shift, another configurable current mirror 700 with a second plurality of switch blocks should be applied also to the fourth node X4 of the slave oscillator 120, the decoder 720 can be shared.

FIG. 7B schematically shows a configurable capacitance block 750, that is used in place of the capacitor C3 of the slave oscillator 120 shown in FIG. 3B, according to still another embodiment of the invention.

The capacitance block 750 comprises a decoder 760 connected to an input bus 790 of N input lines as configuration data, the output thereof providing an output bus 780 of 2^{N} control lines. The capacitance block 750 also comprises a plurality of capacitive units, 770A . . . 770N, each inserted between the third node X3 of the slave oscillator 120 and ground GND. The third node X3 is also connected to ground GND through the sixth switch SW32. In particular, each capacitive unit 770 comprises a first enabling transistor M73 and a capacitor C7, inserted, in series to each other, between the third node X3 and ground GND, the enabling transistor M73 having a control or gate terminal connected to one control line of the output bus 780.

The capacitor C7 of each capacitive unit 770 is able to store a charge being derived by a current flowing through the capacitive unit itself, while the enabling switch M73 is a configuration switch able to switch on or off the current flowing through the capacitive unit 770 according to the data provided by the respective control line of the output bus 780.

In this way, the capacitance value of the configurable capacitance block 750 can be adjusted.

Also in this case, in order to obtain a proper time shift, another configurable capacitance block 750 with a second plurality of capacitive units should be applied also to the fourth node X4 of the slave oscillator 120.

In essence, the configurable capacitance block 750 allows a selection of the time shift between the master and slave clock signals by changing the charging capacitance value and thus the current provided to the slave oscillator 120.

The clock generator according to the embodiments of the present disclosure allows to generate two or more digital clock signals with a precise time shift between them. These clock signals are thus suitable for integrated circuits where an accurate device matching is commonly obtained.

The described clock generator is also suitable to obtain a high precision high frequency digital clock signal.

In this way, changing the period of the generated clock signals is easily obtained as well as different clock signals with a precise time difference between them.

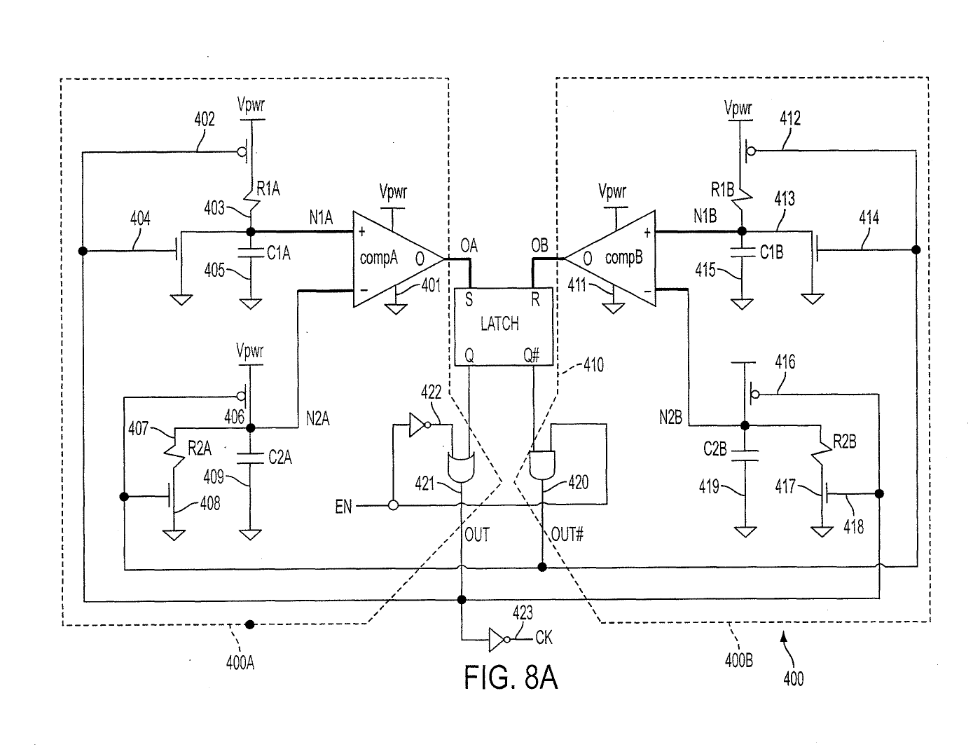

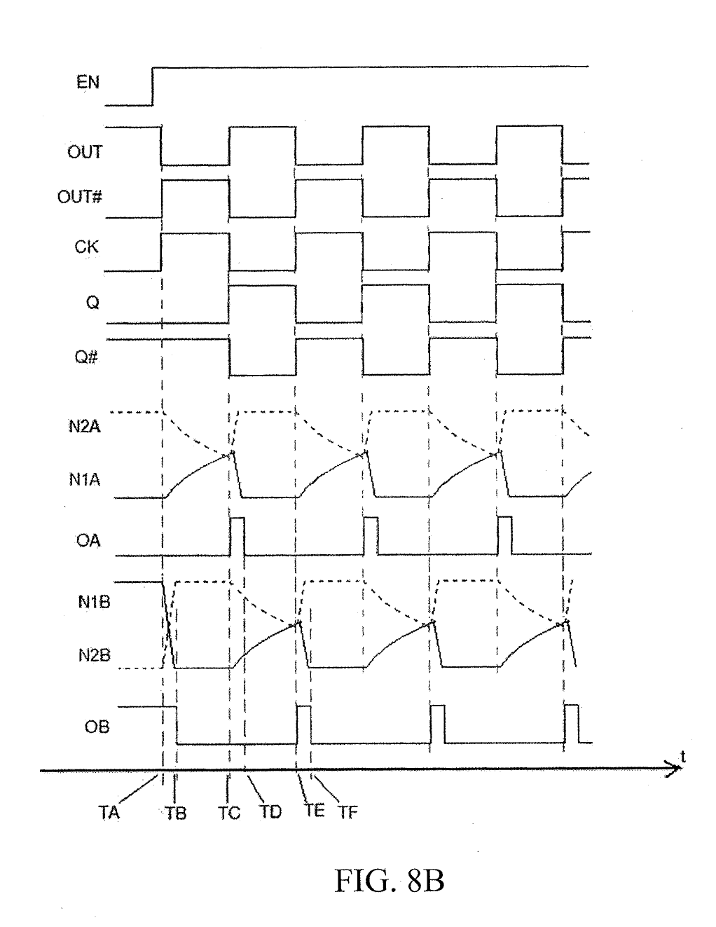

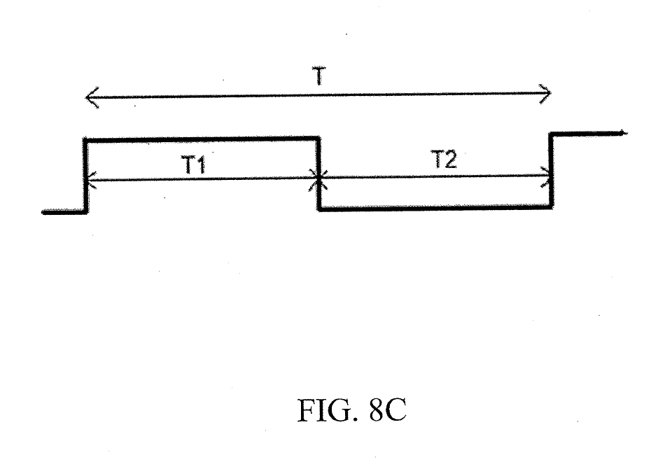

FIG. 8A schematically shows an embodiment of the clock-generator or oscillating circuit according to the present disclosure. FIG. 8B shows exemplary waveforms associated with the circuit in FIG. 8A.

The clock-generator or oscillating circuit according to the seventh embodiment of the present disclosure is configured to generate a clock signal with improved independence from power supply and consequently a higher Power Supply Rejection Ratio (PSSR).

The oscillator or clock generator can generate a clock signal with an improved PSSR.

The oscillator or clock generator can adjust the clock period of the generated clock signal.

The circuit 400 includes a left module 400A, and a right module 400B. The reference voltage may not be constant and may vary according to a voltage level and, therefore, may be dynamically adjusted, which will be explained below with reference to the present embodiment.

The circuit 400 also includes a common latch 410, which is for instance a SR latch but the scope of the invention is not limited thereto. That is, depending on the implementation, other types of latches or flip-flops may be used. In particular, the first common latch 410 has a first input or set terminal S, a second input or reset terminal R, a first output terminal Q and a second output terminal Qb. In this exemplary embodiment, the signal at the second output terminal Qb is the complement of the signal at the first output terminal Q, which means that when Q is high Qb is low, and when Q is high, then Q is low.

More in particular, the left module 400A comprises a comparator CompA 401, a pmos transistor 402, a nmos transistor 404, a resistor R1A 403, as well as a capacitor block including a first capacitor C1A 405. More in particular, the pmos transistor 402, the resistor R1A 403 and the capacitor C1A 405 are inserted, in series to each other, between a power supply voltage Vpwr and ground Vgnd. Also, the pmos transistor 402, the resistor R1A 403 and the nmos transistor 404 are inserted, in series to each other, between Vpwr and Vgnd. A node N1A between the resistor R1A and the capacitor C1A is connected to a non-inverting (+) input of the comparator CompA 401.

The left module 400A further comprises a pmos transistor 406, a nmos transistor 408, a resistor R2A 407, as well as a capacitor block including a second capacitor C2A 409. The pmos transistor 406, the resistor R2A 407 and the nmos transistor 408 are inserted, in series to each other, between a power supply voltage Vpwr and ground Vgnd. Also, the pmos transistor 406 and the capacitor C2A 409 are inserted, in series to each other, between Vpwr and Vgnd. A node N2A between the pmos transistor 406 and the capacitor C2A 409 is connected to an inverting (−) input of the first comparator CompA 401.

The pmos transistor 402 and nmos transistor 404 have respective driving terminals connected to the first output terminal Q of the common latch 410 through a logic gate 421, being a NOR gate. The two input terminals of the NOR gate 421 are connected to the output terminal Q of the latch 410 and the output of a logic gate 422, being a NOT gate, which is then connected to the signal EN.

Further, the pmos transistor 406 and nmos transistor 407 have respective driving terminals connected to the second output terminal Qb of the common latch 410 through a logic gate 420, being a AND gate. The two input terminals of the AND gate 420 are connected to the output terminal Qb of the latch 410 and the signal EN.

In a similar manner, the right module 400B comprises a comparator CompB 411, a pmos transistor 412, a nmos transistor 414, a resistor R1B 413, as well as a capacitor block including a first capacitor C1B 415. More in particular, the pmos transistor 412, the resistor R1B 413 and the capacitor C1B 415 are inserted, in series to each other, between a power supply voltage Vpwr and ground Vgnd. Also, the pmos transistor 412, the resistor R1B 413 and the nmos transistor 414 are inserted, in series to each other, between Vpwr and Vgnd. A node N1B between the resistor R1B and the capacitor C1B is connected to a non-inverting (+) input of the comparator CompB 411.

The right module 400B further comprises a pmos transistor 416, a nmos transistor 418, a resistor R2B 417, as well as a capacitor block including a second capacitor C2B 419. The pmos transistor 416, the resistor R2B 417 and the nmos transistor 418 are inserted, in series to each other, between a power supply voltage Vpwr and ground Vgnd. Also, the pmos transistor 416 and the capacitor C2B 419 are inserted, in series to each other, between Vpwr and Vgnd. A node N2B between the pmos transistor 416 and the capacitor C2B 419 is connected to an inverting (−) input of the first comparator CompB 411.

The pmos transistor 412 and nmos transistor 414 have respective driving terminals connected to the second output terminal Qb of the common latch 410 through a logic gate 420, being a AND gate. The two input terminals of the AND gate 420 are connected to the output terminal Qb of the latch 410 and the signal EN.

Further, the pmos transistor 416 and nmos transistor 417 have respective driving terminals connected to the first output terminal Q of the common latch 410 through a logic gate 421, being a NOR gate. The two input terminals of the NOR gate 421 are connected to the output terminal Q of the latch 410 and the output of a logic gate 422, being a NOT gate, which is then connected to the signal EN.

The operation of the circuit in FIG. 8A is now explained. Provided that no conditions exist for which both OA and OB are at “1” at the same time, when output OA of comparator CompA (401) turns to “1”, output Q of the latch 410 turns to “1” (and Q# to “0”). Q and Q# are kept in the same state until voltage at OB, which is the output of CompB (411), turns to “1”.

Further, the two inputs “+” and “−” of each comparator (CompA and CompB) are connected to two different circuits. Specifically, The “+” input of CompA, N1A, and the “+” input of CompB, N1B, are respectively connected to two capacitor charge circuits, C1A (405) and C1B (415). The “−” input of CompA, N2A, and the “−” input of CompB, N2B, are respectively connected to two capacitor discharging circuits, C2A (409) and C2B (419). Thus, circuits 400A and 400B may each be implemented through the same or at least a similar circuit structure to operate complementally to each other such that the circuit 400 generates a first signal and a second signal having an opposite phase to that of the first signal.

When N1A>N2A, the output OA turns from “0” to “1”, and the output Q is then triggered to commute from “0” to “1” (and Q# from “1” to “0”). When N1B>N2B, the output OB turns from “0” to “1”, and the output Q is then triggered to commute from “1” to “0” (and Q# from “0” to “1”). The two conditions can alternate, and one round of these conditions can complete one cycle or oscillation.

Switches connected to Vpwr and Vgnd may be realized in relative a simple way as follows: Pmos transistors 402, 412, 406 and 416 are used as switches connected to Vpwr, which are closed when the gate voltage is at “0” and opened when the gate voltage is at “1”. Nmos transistors 404, 414, 408 and 418 are used as switches connected to Vgnd, which are closed when the gate voltage is “1” and opened when the gate voltage is at “0”.

The logic constituted by gates 422, 421 and 420 is used as a startup circuit. Inverter 423 is used to buffer the OUT node before obtaining the clock signal CK.

The circuit in FIG. 8A achieves, among other, obtaining trigger points of for CompA (401) and CompB (411) that are independent of power supply variations. Provided that the two comparators are identical, this independence from Vpwr will make the non-zero delay of the comparators identical. The period T of the square waveform CK (see FIG. 8C) will hence be independent from Vpwr variation, and the semi-periods T1 and T2 (see FIG. 8C) may be determined only by the values of resistors 403, 413, 407 and 417 and values of capacitors 405, 415, 409 and 419.

FIG. 8B shows the waveforms of the circuit of FIG. 8A. The operation of the circuit in FIG. 8A is further explained with reference to the waveforms in FIG. 8B.

Before time TA, when EN is low, node OUT is kept at “1” and node OUT# is kept at “0”.

At time TA, as EN commutes to “1” thereafter, the output OUT (and OUT#) changes the state, and the oscillation process is started. OR gate 421 triggers OUT to “0”. AND gate 420 triggers OUT# to “1”. With EN=“1”, OUT=Q and OUT#=Q#, when OUT goes to “0” (see time TA in FIG. 8B), transistor 402 turns ON and 404 turns OFF. Node N1A starts charging to Vpwr, depending on the resistance value of 403 and the capacitance value of 405.

On the other hand, due to OUT# that is commuting, or has commuted, to “1”, transistor 406 turns OFF and 408 turns ON. Node N2A starts discharging towards Vgnd depending on the resistance value of 407 and the capacitance value of 409.

Further due to OUT# commuting to “1”, transistor 412 turns OFF and 414 turns ON. Node N1B is, therefore, discharged to Vgnd. At the same time, due to OUT commuting to “0”, transistor 416 turns ON and 418 turns OFF. Node N2B is, therefore, charged to Vpwr. The discharging and charging may occur relatively fast.

At time TB, as a consequence, OB commutes from “1” to “0”, and reset pin R is de-asserted (see time TB in FIG. 8B). The latch subsequently enters the latching state, waiting for a set pulse. From this point onwards, nothing evolves on the B-side (including, e.g., compB, N1B, N2B, R1B, R2B, C1B, C2B, etc) until Q and Q# start commuting.

At time TC, when N1A rises above N2A (see time TC in FIG. 8B), comparator 401 outputs “1” (OA=“1”). The latch then has a set pulse on pin S, and the output Q of the latch commutes to “1” (and Q# to “0”). As a consequence, N1A is discharged to Vgnd via 404, and N2A is charged to Vpwr via 406. Since N1A and N2A are the two inputs of the compA (401), the output OA of compA (401) starts commuting to ground, “0”.

At time TD, the output OA of compA (401) becomes “0”. The set pulse on pin S of the latch is de-asserted (see time TD in FIG. 8B). The latch then enters the latching state, waiting for a reset pulse. From this point onwards, nothing evolves on the A-side (including, e.g., compA, N1A, N2A, R1A, R2A, C1A, C2A, etc) until Q and Q# start commuting.

At time TC, referring to the other side of the circuit (B-side), at time TC, due to OUT# commuting to “0”, transistor 412 turns ON and 414 turns OFF. Node N1B starts charging to Vpwr depending on the resistance value of 413 and the capacitance value of 415.

Still at time TC, due to OUT commuting to “1”, transistor 416 turns OFF and 418 turns ON. Node N2B starts discharging towards Vgnd depending on the resistance value of 417 and the capacitance value of 419. As described above, the evolution of the circuit on the B-side may be similar to that on the A-side, but this similarity is not a requirement for the practice of the invention disclosed in the present embodiment.

At time TE, when N1B rises above N2B (see time TE in FIG. 8B), comparator compB (411) outputs “1” (OB=“1”). The latch then has a reset pulse on pin R, and the output Q of the latch commutes to “0” (and Q# to “1”). As a consequence, N1B is discharged to Vgnd via 414, and N2B is charged to Vpwr via 416. Since N1B and N2B are the two inputs of the compB (411), the output OA of compB starts commuting to ground, “0”.

At time TF, the output OA of compB (411) becomes “0”. The reset pulse on pin R of the latch is de-asserted (see time TF in FIG. 8B). The latch then enters the latching state, waiting for a set pulse. From this point onwards, nothing evolves on the B-side until Q and Q# start commuting. This completes a cycle or one oscillation, and the above may be repeated until EN turns to “0”.

In this manner, the square waveform generated at output Q is independent from Vpwr, and consequently is independent from the variations of Vpwr.

<Clock with Trimming Options>

The circuit architecture shown in FIG. 8A may be modified so that the circuit may trim the clock period (T′) or the duty cycle (D) of the generated clock signal.

The trimming options may allow the clock generator to compensate any processing errors or variations, which in turn cause errors or variations in the clock period of the generated clock signal. Such a trimming operation may be done in a test period during the circuit's manufacturing or fabrication process. Further, logical values of control signals TR may be fixed according to storages such as a fuse, an anti-fuse, a CAM, or a non-volatile memory.

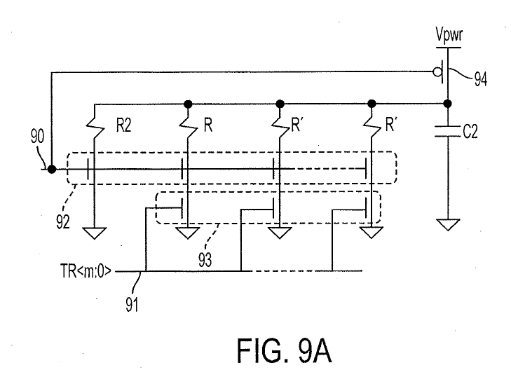

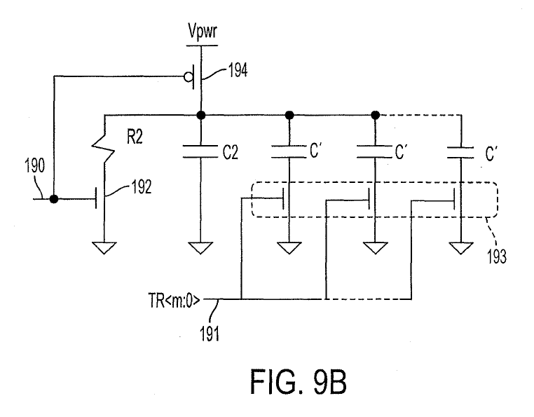

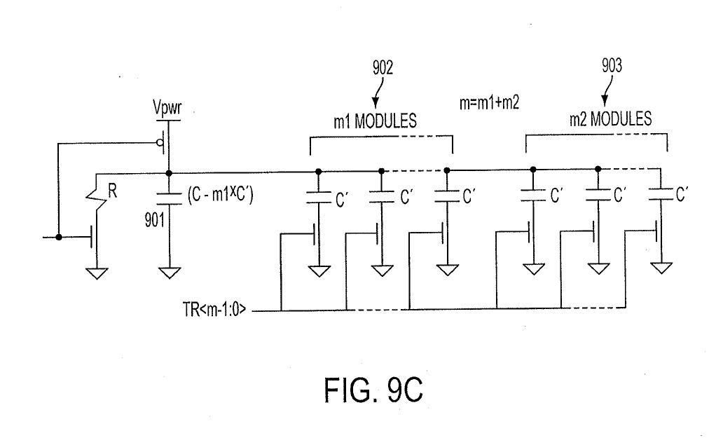

FIG. 9A schematically shows an eighth embodiment of the clock generator according to the present disclosure with trimming options.

The total resistance of the circuit may be varied by adding or removing extra resistor modules R′ in addition to reference resistor R2. The resistor modules R′ are connected in parallel to the reference resistor R2. The reference resistor R2 may correspond to resistors R1A 403, R2A 407, R1B 413, and/or R2B 417 in the circuit shown in FIG. 8A. The resistor modules R′ may all have the same resistance value or different resistance values depending on the required design specification.

A plurality of transistors 92 are provided. One of the transistors 92 is inserted between the reference resistor R2 and the ground. The others of the transistors 92 are inserted respectively between an associated one of the extra resistor modules R′ and the ground. A plurality of select transistors 93 are provided. The select transistors 93 are inserted respectively between an associated one of the transistor 92 and the ground. The line 90 is coupled in common to the gate of the PMOS transistor 94 and the gates of the transistors 92 to turn those transistors on or off. A plurality of lines 91 are provided to convey signals TR<m:0>. Each of the lines 91 is coupled to a gate of an associated one of the select transistors 93 to turn the associated transistor on or off.

The number of resistor modules (R′) may be any number between 1 and ‘m’, and each of the modules is inserted between the ground and the node between the pmos transistor 92 and capacitor C2.

The pmos transistor 92 shown in FIG. 9A may correspond to transistors 402, 406, 412 and/or 416 in the circuit shown in FIG. 8A. Capacitor C2 shown in FIG. 9A may correspond to capacitors C1A 405, C2A 409, C1B 415, and/or C2B 419 in the circuit shown in FIG. 8A.

The value of the total resistance is increased by connecting additional resistors (R′) and is decreased by disconnecting resistors (R′) from the circuit. The connection/disconnection is controlled by control signal TR<m:0>.

If the total resistance value is increased, the associated time constant value, τ=RC, is increased (e.g., the clock period T′ is widened), and if the total resistance value decreased, the time constant value is decreased (e.g., the clock period T′ is narrowed).

FIG. 9B schematically shows a ninth embodiment of the clock generator according to the present disclosure with trimming options.

The total capacitance of the circuit may be varied by adding or removing extra capacitor modules C′ in addition to reference capacitor C2. The capacitor modules C′ are connected in parallel to the reference capacitor C2. The reference capacitor C2 may correspond to capacitors C1A 405, C2A 409, C1B 415, and/or C2B 419 in the circuit shown in FIG. 8A. The capacitor modules C′ may all have the same capacitance value or different capacitance values depending on the required design specification.

A plurality of select transistors 193 are provided. The select transistors 193 are inserted respectively between an associated one of the capacitor (modules) C′ and the ground. The line 190 is coupled in common to the gate of the PMOS transistor 194 and the gate of the NMOS transistor 192 to turn those transistors on or off. A plurality of lines 191 are provided to convey signals TR<m:0>. Each of the lines 191 is coupled to a gate of an associated one of the select transistors 193 to select the associated transistor respectively on or off.

The number of capacitor modules (C′) may be any number between 1 and ‘m’, and each of the modules is inserted between the ground and the node between the pmos transistor and capacitor C2.

The value of the total capacitance is increased by connecting additional capacitors C′ and is decreased by disconnecting capacitors C′ from the circuit. The connection/disconnection of the capacitors C′ is controlled by control signal TR<m:0>.

If the total capacitance value is increased, the associated time constant value, τ=RC, is increased (e.g., the clock period T′ is widened), and if the total resistance value decreased, the time constant value is decreased (e.g., the clock period T′ is narrowed).

However, in the above embodiments, the time constant value may only be increased compared to the default time constant value when no R′ or C′ is connected (when m=0), since any parallel connection of R′ and/or C′ increases the respective total resistance and/or capacitance. The next embodiment shows how to achieve a time constant value that is even smaller than the default time constant value.

In another example, the circuits shown in FIGS. 9A and 9b may be combined such that the PMOS transistor 94 and line 90 shown in FIG. 9A is identical respectively to the PMOS transistor 194 and the line 190 shown in FIG. 9B.

FIG. 9C schematically shows a tenth embodiment of the clock generator according to the present disclosure with the trimming options.

Even though FIG. 9C shows one possible modification that may be made to the embodiment shown in FIG. 9B, the same concept may be applied to the embodiment shown in FIG. 9A.

In FIG. 9C, a fixed capacitor 901 has the capacitance value equal to C−m1*C. Similar to the above embodiments, there are ‘m’ number of selectable capacitor modules C′. Forsake of explanation, it is assumed that these capacitor modules C′ all have the same capacitance value C′. Among the total ‘m’ number of the capacitor modules, ‘m1’ number of the capacitor modules 902 are pre-connected in parallel to the fixed capacitor 901, and may be selectively disconnected by the control signal, TR<m1−1:0>. The remaining m2 (m2=m−m1) number of modules 903 are pre-disconnected from the fixed capacitor 901, and may be selectively connected by the control signal, TR<m−1:m1>.

TABLE 4 below shows the general relationship between the control signals, number of disconnected m1 modules, number of connected m2 modules, and the total

TABLE 4
Trimming of capacitance for the general cases of m, m1 and m2

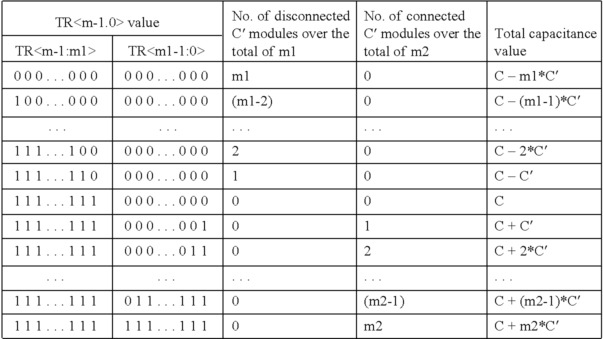

capacitance value experienced by the circuit. The TABLE 5 below shows the specific case when the total number of modules is 8 (m=8), m1 is 4, and m2 is 4. In these tables, the highlighted line corresponds to the central value for the capacitance, which occurs when all of the m1 modules are connected and all of the m2 modules are disconnected.

TABLE 5
Trimming of capacitance for the case of m = 8, m1 = 4, and m2 = 4.

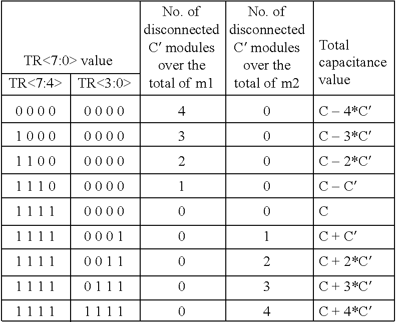

In this manner, the total resistance value and total capacitance value of the clock generator circuit may be controlled. Also, each of the additional resistor modules (R′) and/or capacitor modules (C′) may all have the same resistance and capacitance value, respectively, or different resistance and capacitance value, depending on the technical requirements of the circuit. In particular, with use of the resistor or capacitors modules with different respective values, a linear tuning relationship may be achieved—that is, the clock period T is tunable in fixed amplitude steps (for example, in steps of 1 ns).

Still further, any combination of the fixed and variable modules is possible. For example, a first m1 number of the capacitor/resistor modules that are selectively-connectable may have the fixed capacitance/resistance value C′ or R′ respectively, while a second m2 number of the capacitor/resistor modules may have a different capacitance/resistance value.

In this manner, a flexible adjustment or trimming of the clock period (T′) is possible—the clock period may both be trimmed upward (extended) and downward (narrowed) from its central value.

From the foregoing it will be appreciated that, although specific embodiments of the clock generator or oscillator according to the present disclosure have been described herein for purposes of illustration, various modifications may be made without deviating from the spirit and core principle of the disclosure.

What is claimed:

1. A device comprising:
a clock generating circuit including:
a first comparator circuit and a second comparator circuit which work complementary to each other to generate a first signal and a second signal having an opposite phase to the first signal;
a first reference circuit including a first capacitor and a first resistance to produce, in response to the second signal, a first reference voltage supplied to the first comparator circuit; and
a second reference circuit including a second capacitor and a second resistance to produce, in response to the first signal, a second reference voltage supplied to the second comparator circuit.

2. The device as claimed in claim 1, wherein the clock generating circuit further includes:
a first preceding circuit including a third capacitor and a third resistance to produce, in response to the first signal, a first comparison voltage compared by the first comparator circuit with the first reference voltage; and
a second preceding circuit including a fourth capacitor and a fourth resistor to produce, in response to the second signal, a second comparison voltage compared by the second comparator with the second reference voltage.

3. The device as claimed in claim 1, wherein the first reference circuit and the second reference circuit are substantially same in a circuit structure as each other.

4. The device as claimed in claim 2, wherein the first preceding circuit and the second preceding circuit are substantially same in a circuit structure as each other.

5. The device as claimed in claim 1, wherein the first reference circuit of the clock generating circuit further includes:
a first transistor coupled between a first power supply line and a reference input node of the first comparator and including a gate supplied with the second signal;
a second transistor coupled between the reference input node of the first comparator and a second power supply line and including a gate supplied with the second signal;
the first capacitor coupled between the reference input node of the first comparator and the second power supply line; and
the first resistance coupled between the reference input node of the first comparator and the second transistor;
and wherein the second reference circuit of the clock generating circuit further includes:
a third transistor coupled between the first power supply line and a reference input node of the second comparator and including a gate supplied with the first signal;
a second transistor coupled between the reference input node of the second comparator and a second power supply line and including a gate supplied with the first signal;
the second capacitor coupled between the reference input node of the second comparator and the second power supply line; and
the second resistance coupled between the reference input node of the second comparator and the fourth transistor.

6. The device as claimed in claim 1, further comprising:
a memory;
a circuit controlling the memory in response to the first and second signal supplied from the clock generating circuit.

7. The device as claimed in claim 1, wherein the memory includes a NAND flash memory.

8. A device comprising:
a clock generating circuit including:
a first comparator circuit and a second comparator circuit which work complementary to each other to generate a first signal and a second signal having an opposite phase to the first signal;
a first reference circuit producing, in response to the second signal, a first reference voltage supplied to the first comparator circuit, and including:
a first transistor coupled between a first power supply line and a reference input node of the first comparator and including a gate supplied with the second signal;
a second transistor coupled between the reference input node of the first comparator and a second power supply line and including a gate supplied with the second signal;
a first capacitor coupled between the reference input node of the first comparator and the second power supply line; and
a first resistance coupled between the reference input node of the first comparator and the second transistor.

9. The device as claimed in claim 8, wherein the clock generating circuit further includes:
a first preceding circuit producing, in response to the first signal, a first comparison voltage compared by the first comparator circuit with the first reference voltage, and including:
a second transistor coupled between the first power supply line and a comparison node of the first comparator circuit and including a gate supplied with the first signal;
a second transistor coupled between the comparison node of the first comparator circuit and the second power supply line and including a gate supplied with the first signal;
a second capacitor coupled between the comparison node of the first comparator circuit and the second power supply line; and
a second resistance coupled between the first transistor and the comparison node of the first comparator circuit.

10. The device as claimed in claim 8, further comprising:
a memory;
a circuit controlling the memory in response to the first and second signal supplied from the clock generating circuit.

11. The device as claimed in claim 10, wherein the memory includes a NAND flash memory.

12. A device comprising:
a clock generating circuit including:
a first comparator circuit and a second comparator circuit which work complementary to each other to generate a first signal and a second signal having an opposite phase to the first signal;
a first reference circuit producing, in response to the second signal, a first reference voltage supplied to the first comparator circuit, the first reference voltage varying in a voltage level; and
a second reference circuit producing, in response to the first signal, a second reference voltage supplied to the second comparator circuit, the second reference voltage varying in a voltage level.

13. The device as claimed in claim 12, wherein a first time period that the first reference voltage varies from a first voltage level to a second voltage level is shorter than a second time period that the first reference voltage varies from the second voltage level to the first voltage level, and
a third time period that the second reference voltage varies from the first voltage level to the second voltage level is shorter than a fourth time period that the second reference voltage varies from the second voltage level to the first voltage level.

14. The device as claimed in claim 12, wherein the clock generating circuit further includes:
a first preceding circuit producing, in response to the first signal, a first comparison voltage compared by the first comparator circuit with the first reference voltage, the first comparison voltage varying in a voltage level;
a second preceding circuit producing, in response to the second signal, a second comparison voltage compared by the second comparator with the second reference voltage, the second comparison voltage varying in a voltage level.

15. The device as claimed in claim 14, wherein a fifth time period that the first comparison voltage varies from a third voltage level to the second voltage level is identical to a first time period that the first reference voltage varies from a first voltage level to the second voltage level, and
a sixth time period that the second comparison voltage varies from the third voltage level to the second voltage level is identical to a third time period that the second reference voltage varies from the first voltage level to the second voltage level.

16. The device as claimed in claim 15, wherein the first signal takes a first level in the fifth time period, and the second signal takes a second level different from the first level in the fifth time period, and
wherein the first signal takes the first level in the sixth time period, and the second signal takes the first level in the sixth time period.
